(19) United States
(12) Patent Application Publication
(10) Pub. No.: US 2025/0062273 A1
(43) Pub. Date: Feb. 20, 2025

(54) Package with Vertical Electronic Components Held Together by a Clip

(71) Applicant: Infineon Technologies Austria AG, Villach (AT)

(72) Inventors: Chee Yang Ng, Muar (MY); Chee Hong Lee, Muar (MY); Kok Yau Chua, Melaka (MY); Shih Kien Long, Tengkera (MY); Chee Voon Tan, Seremban (MY); Jayaganasan Narayanasamy, Durian Tunggal (MY)

(21) Appl. No.: 18/795,242

(22) Filed: Aug. 6, 2024

(30) Foreign Application Priority Data
Aug. 16, 2023 (DE) 102023121936.7

(51) Int. Cl. H01L 23/00; H01L 23/31; H05K 1/18

(52) U.S. Cl. CPC H01L 24/72; H01L 23/3121; H05K 1/181; H01L 2224/72; H01L 2924/153; H05K 2201/10386

(57) ABSTRACT

A package includes: a vertically extending first electronic component with at least one exposed electrically conductive first terminal; a vertically extending second electronic component with at least one exposed electrically conductive second terminal; and a clip with an accommodation volume in which the first electronic component and the second electronic component are accommodated and are held together. The at least one first terminal and the at least one second terminal are electrically accessible at a bottom of the clip.

### TECHNICAL FIELD

Various embodiments relate generally to a package, and a method of manufacturing a package.

### BACKGROUND

A conventional package may comprise an electronic component mounted on a chip carrier, may be electrically connected by a bond wire extending from the chip to the chip carrier or to a lead, and may be molded using a mold compound as an encapsulant.

Space consumption of a conventional package may be an issue.

### SUMMARY

There may be a need for a compact package with high reliability and reasonable or low manufacturing effort.

According to an exemplary embodiment, a package is provided which comprises a vertically extending first electronic component with at least one exposed electrically conductive first terminal, a vertically extending second electronic component with at least one exposed electrically conductive second terminal, and a clip with an accommodation volume in which the first electronic component and the second electronic component are accommodated and are held together, wherein the at least one first terminal and the at least one second terminal are electrically accessible at a bottom of the clip.

According to another exemplary embodiment, a method of manufacturing a package is provided, the method comprising inserting a vertically extending first electronic component with at least one exposed electrically conductive first terminal in an accommodation volume of a clip, inserting a vertically extending second electronic component with at least one exposed electrically conductive second terminal in the accommodation volume of the clip, holding together the first electronic component and the second electronic component in the accommodation volume by the clip, and configuring the first electronic component, the second electronic component and the clip so that the at least one first terminal and the at least one second terminal are electrically accessible at a bottom of the clip.

According to an exemplary embodiment, a package comprises at least two vertically extending electronic components each having one or more exposed terminals. Advantageously, a clip receives in its accommodation volume and holds both electronic components in their vertical orientation. The design of the package may be so that terminals of the electronic components can be accessed electrically at a bottom side of the clip. Such a package design has the beneficial effect that due to the vertical arrangement of the electronic components, the package footprint and therefore spatial dimensions of the package may be very small. Thus, a high integration density may be achieved with the described package concept. At the same time, the clip does not only fulfill a mechanical protection function by accommodating and at least partially surrounding the electronic components therein, but also contributes to the electronic functionality of the package by enabling an access of the components' terminals at a clip bottom. For manufacturing packages, insertion of the vertically oriented electronic components in the accommodation volume may be an easy task, which may simplify manufacturability compared with conventional approaches. Consequently, a package according to an exemplary embodiment may be compact, may have a high reliability and may be producible in an easy way.

In the following, further exemplary embodiments of the package and the method will be explained.

In the context of the present application, the term “package” may particularly denote an electronic device which may comprise electrically connected electronic components. Said constituents of the package may be optionally encapsulated by an encapsulant. Further optionally, one or more electrically conductive interconnect bodies (such as metallic pillars, pumps, bond wires, conductive plates and/or clips) may be implemented in a package, for instance for electrically coupling and/or mechanically supporting the electronic components. It is also possible that one or more carriers form part of the package, for instance a metallic carrier contributing to the electronic functionality.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may comprise a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed for example in silicon technology, gallium nitride technology, silicon carbide technology, etc.

In the context of the present application, the term “vertically extending electronic component” may particularly denote an electronic component being arranged so that its thickness direction extends horizontally and/or its main surfaces extend vertically. The main surfaces may be two opposing surfaces of the electronic components with largest areas. An active region of a semiconductor chip-type electronic component may extend in a vertical plane when the assigned electronic component is inserted in the accommodation volume of the clip and when the bottom of the clip is located on a horizontal surface. In a scenario in which a vertically extending electronic component has a cuboid shape or a substantially cuboid shape, the smallest dimension of the electronic component may extend horizontally. At a vertically extending electronic component, its terminals may have vertical exposed surface areas.

In the context of the present application, the term “clip” may particularly denote a physical structure defining an accommodation volume therein and being configured for applying a holding force (such as a clamping force and/or a connection force by a connection medium like solder) when two (or more) vertically oriented electronic components are inserted as a stack or sandwich in the accommodation volume of the clip. More specifically, a clip of a preferred embodiment may be a clamp designed to bind or to constrict or to press two or more parts (including at least two vertically extending electronic components) together so as to hold them firmly. For instance, a clamp-type clip may exert an elastic force (for instance a spring force) to the vertically extending electronic components for holding them together tightly.

In the context of the present application, the term “terminal” may particularly denote an electrically conductive interface element (such as a metallic pad) of the electronic component being accessible for conducting an electric signal or electric power towards the electronic component and/or away from the electronic component. In particular, a respective electronic component may be a chip with integrated transistor. Such a transistor may be a field-effect transistor chip having a source terminal (or pad), a drain terminal (or pad) and a gate terminal (or pad). Alternatively, a respective chip with integrated transistor may be a bipolar transistor chip having an emitter terminal (or pad), a collector terminal (or pad) and a base terminal (or pad). A diode-type electronic component may have a cathode terminal and an anode terminal.

In the context of the present application, the term “terminal electrically accessible at a bottom of the clip” may particularly denote that electrically conductive structures are exposed at the bottom side of the clip which can be contacted for establishing an electrically conductive connection to the respective terminals of the electronic components. For instance, this may be accomplished by the clip itself when made of an at least partially electrically conductive material and when exerting a holding force on a terminal of one of the electronic components, so that contacting the bottom side of the clip allows to electrically connect to or access said terminal. It is also possible that one of the terminals itself is directly accessible at the bottom of the clip. In yet another embodiment, a terminal of one of the electronic components may be accessible at the bottom of the clip by a further electrically conductive element, such as a metallic carrier, which is electrically coupled, in turn, with the respective terminal.

In an embodiment, at least one of the first electronic component and the second electronic component is a bare die, a die encapsulated by an encapsulant, a plurality of dies encapsulated by an encapsulant, a bare die mounted on a conductive element (such as a carrier), or a bare die connected between two conductive elements. In the context of the present application, the term “bare die” may be a non-encapsulated semiconductor chip. In the context of the present application, the term “encapsulant” may particularly denote a substantially electrically insulating material surrounding a die to provide mechanical protection, electrical insulation, and optionally a contribution to heat removal during operation. In particular, said encapsulant may be a mold compound. A mold compound may comprise a matrix of flowable and hardenable material and filler particles embedded therein. As an alternative to a mold compound (for example on the basis of epoxy resin), the encapsulant may also be a potting compound (for instance on the basis of a silicone gel). In the context of the present application, the term “conductive element” may particularly denote an at least partially electrically conductive carrier or a support structure (such as a metallic plate) which serves as a mechanical support for the electronic component(s) to be mounted thereon, and which may also contribute to the electric interconnection between the electronic component(s) and the periphery of the package. In other words, a carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate.

In particular, the package can be configured in accordance with the following three embodiments: In a first embodiment, the clip is a clamp which clamps together the first vertically extending component and the second vertically extending electronic component. In a second embodiment, the clip is attached to the first vertically extending electronic component and/or to the second vertically extending electronic component via a clip connection medium, like glue or solder. In a third embodiment, holding by clamping according to the first embodiment and holding by a connection medium according to the second embodiment may be combined.

In an embodiment, the clip is configured for clamping together the first electronic component and the second electronic component in the accommodation volume by a clamping force. For instance, a clamping force exerted by the clip to the electronic components may be the only connection force for connecting the electronic components. This may lead to a very simple design. Alternatively, a clamping force exerted by a clamp-type clip may be supplemented by a connection medium (like a solder or a glue) connecting clip with electronic component(s) and/or connecting the electronic components with each other.

In an embodiment, the clip is electrically conductive. Preferably, an electrically conductive connection is established between the clip and at least one of said at least one first terminal and said at least one second terminal by the holding, for example clamping. For example, an electric signal or electric power may flow from a terminal of an electronic component to the electrically conductive clip, or vice versa. It is also possible that an electric signal or electric power may flow from a first terminal of the first electronic component via the electrically conductive clip to the second terminal of the second electronic component, or vice versa. Advantageously, the clip may then contribute to the electric function of the package. For example, the clip may be directly clamped or integrally connected (for example soldered) onto an electrically conductive terminal of at least one of the electronic components with direct physical contact so that, apart from providing a mechanical connection and protection function, the clip may also conduct an electric signal or electric power to or from the terminal.

In an embodiment, an electrically conductive connection is established (for example with direct physical contact or with a connection medium in between) between at least one of said at least one first terminal and at least one of said at least one second terminal by the holding. Hence, an electric signal or electric power may flow from a first terminal of the first electronic component directly or only via a connection medium in between to the second terminal of the second electronic component, or vice versa. The clip may then fulfill a double function, i.e. a mechanical holding function and an electric connection function.

In an embodiment, the package comprises a component connection medium, for example glue or solder, connecting the first electronic component with the second electronic component in the accommodation volume. By integrally connecting the first electronic component and the second electronic component with each other by a component connection medium, the reliability of the package may be further improved. Alternatively or in addition to a clamping, a permanent connection may thus be established between the two (or more) electronic components by gluing, soldering, sintering, etc. For instance, one main surface of the electronic components may be connected with the clip, whereas the opposing main surface of the electronic components may be connected with each other by a component connection medium. For example, a solder attachment (or an attachment using another component connection medium) between the electronic components can be done in addition to clamping. In another embodiment, a solder attachment (or an attachment using another component connection medium) between the electronic components can be done as an alternative to clamping.

In an embodiment, the component connection medium connects at least one of the at least one first terminal and at least one of the at least one second terminal with each other. In such a scenario, it may be advantageous that the component connection medium is electrically conductive. The component connection medium may reliably connect the electronic components with each other, and may also generate an electrically conductive connection in between, for instance for transmitting electric power or electric signals.

In an embodiment, the package comprises a clip connection medium, for example glue or solder, connecting the clip with at least one of the first electronic component and the second electronic component in the accommodation volume. Such a configuration may ensure mechanical and/or electric reliability of the electronic device. For instance, a clamping connection between clip and electronic component(s) may be enhanced by an additional permanent connection established by the clip connection medium. Alternatively, a permanent connection established by the clip connection medium may be the only connection between clip and electronic component(s). When the clip connection medium is electrically conductive, it can also promote an electric coupling between a terminal of a respective electronic component and an electrically conductive clip. For example, a solder attachment (or an attachment using another clip connection medium) between clip and electronic component(s) can be done in addition to clamping. In another embodiment, a solder attachment (or an attachment using another clip connection medium) between clip and electronic component(s) can be done as an alternative to clamping.

In an embodiment, the clip has a lateral extension section at its bottom. For instance, the lateral extension section may extend in a horizontal direction laterally or radially outwardly from a central access opening of the clip. The clip may have a holding section in which a holding force can be exerted to the electronic components, wherein the lateral extension section may extend laterally from such a holding section. The lateral extension section may promote assembly of the package on a mounting base (such as a printed circuit board) by increasing the usable connection area. For instance, the lateral extension section may comprise two separate opposing lateral extension elements, or may have an annular shape.

In an embodiment, the package comprises a mounting base electrically and mechanically connected with the first electronic component, the second electronic component, and the clip at its bottom. For instance, such a mounting base may be a printed circuit board (PCB). The package may be surface mounted on the mounting base. Since the terminals of the electronic components may be all accessible at the bottom of the clip, connecting the clip on the mounting base by an electrically conductive connection medium (such as a solder or a sinter material) may establish a mechanical and electrical connection between the electronic components and the mounting base.

In an embodiment, the clip has a head (which may face away from the bottom) connected to a lateral holding section delimiting said accommodation volume and leading up to an end sided exterior access opening. Advantageously but not necessarily, the head may be a closed head. The lateral holding section, for instance two lateral holding legs, may extend from the head downwardly and may exert the actual holding (for example clamping) force to the electronic components. The head may protect the electronic components inside the accommodation volume.

In an embodiment, said clip has two spaced legs connected by a head. Such a clip may apply a holding (in particular clamping) force to connect the electronic components. A clip of this type may have two separate legs applying the clamping force. Alternatively, the clip may be a cap with a head connected with a circumferentially closed holding sleeve, for example a centrally confined sleeve. A cap-type clip may be annularly closed for providing full-perimeter protection and holding (in particular clamping) performance. Advantageously but not necessarily, the head may be a closed head.

In an embodiment, a vertical extension of the first electronic component and/or of the second electronic component along an insertion direction into the accommodation volume is larger than another extension of the first electronic component and/or of the second electronic component perpendicular to said insertion direction or along a clamping force direction. In particular, the largest spatial extension of the first electronic component and/or of the second electronic component may be in vertical direction, i.e. along an insertion direction of the respective electronic component into the accommodation volume. The described configurations may lead to a highly compact design.

In an embodiment, each of the at least one first terminal and the at least one second terminal has an exterior planar surface arranged vertically or perpendicular to a clamping force direction. Such terminals may be electrically and mechanically connected with interior surface areas of the clip and/or may be mechanically connected with a facing terminal of the respectively other electronic component.

In an embodiment, the package comprises a thermal interface body having a recess receiving at least part of the clip. The thermal interface body may comprise a thermal interface material (TIM). Such a thermal interface material may for instance be a thermal paste providing a thermal coupling with a heat sink with low thermal resistance in between. The thermal interface body may contribute to a removal of heat generated by the electronic components during operation of the package.

In an embodiment, the package comprises a heat sink attached to an exterior of the thermal interface body. An appropriate heat sink may be a heat dissipation body, which may be made of a highly thermally conductive material such as copper or aluminum. For instance, such a heat sink may have a base body facing said thermal interface body and may have a plurality of cooling fins extending from the base body and in parallel to each another so as to remove the heat towards the environment.

In an embodiment, the thermal interface body tapers from said heat sink towards said clip. Such an embodiment is shown for instance in FIG. 7. The described configuration allows to use an enlarged heat sink in combination with a compact package. Furthermore, this design may result in an efficient heat spreading. Thus, size reduction may be combined with excellent thermal performance.

In an embodiment, at least one of the at least one first terminal and the at least one second terminal is electrically accessible at the bottom of the clip by being electrically coupled with the clip which comprises an electrically conductive material. In other words, the electric accessibility of the respective terminal may be accomplished indirectly by an at least partially electrically conductive clip which allows access at its bottom side and which may be electrically connected with the terminal to be accessed.

In an embodiment, at least one of the at least one first terminal and the at least one second terminal is electrically accessible directly at an exposed bottom of the first electronic component and/or at an exposed bottom of the second electronic component. The clip may have an open bottom at which at least part of the terminals of the electronic components inserted into the accommodation volume of the clip may be directly accessible. Thus, it may be sufficient to only mount a bottom of the package, including a bottom of the clip, on a mounting base for getting direct access to one, some or all terminals of both electronic components.

In an embodiment, a central portion of the clip is connected with (for instance directly contacts) the first electronic component and the second electronic component, wherein the bottom of the clip is laterally spaced by a gap with respect to the first electronic component and the second electronic component. In other words, a gap may be formed between the bottom of the clip and the bottom of the electronic components being held (for example clamp-connected) by the clip, so that central portions of clip and electronic components may be held (preferably clamped) together. Moreover, a further gap may be optionally formed between the top of the clip and the top of the electronic components. This may increase a mounting surface on the bottom side and a cooling surface on the top side while concentrating the clamping force in a central section. Furthermore, such a design may lead to large creepage distances at the bottom of the clip.

In an embodiment, at least one of the first electronic component and the second electronic component comprises a transistor chip, i.e. a chip with integrated transistor. This may in particular denote a chip, such as a semiconductor chip, in which at least a transistor may be integrated, in particular monolithically integrated. In particular, a respective chip with integrated transistor may be a field-effect transistor chip having a source terminal (or pad), a drain terminal (or pad) and a gate terminal (or pad). Alternatively, a respective chip with integrated transistor may be a bipolar transistor chip having an emitter terminal (or pad), a collector terminal (or pad) and a base terminal (or pad). Specific examples of the transistor chips are a metal oxide semiconductor field effect transistor (MOSFET), and an insulated-gate bipolar transistor (IGBT).

In an embodiment, the package comprises at least one further first electronic component, at least one further second electronic component and at least one further clip having the above-mentioned features, wherein a common mounting base is connected with the clip, the first electronic component, the second electronic component, the at least one further clip, the at least one further first electronic component and the at least one further second electronic component. Such an embodiment is shown in FIG. 8. A plurality of clips with inserted electronic components may be surface mounted on the same mounting base. This may allow to implement even sophisticated electronic functionality in a compact way and may allow to execute an efficient warpage management.

In an embodiment, the package comprises at least one further first electronic component, at least one further second electronic component and at least one further clip having the above-mentioned features, wherein a common thermal interface body has recesses receiving at least part of the clip and at least part of the at least one further clip. For such an embodiment, reference is made again to FIG. 8. The various clips with inserted electronic components may not only share a common mounting base, but may also share a common interface body and heat sink. This may contribute to the compactness of the package and to an excellent thermal performance.

In an embodiment, a bottom of the first electronic component and a bottom of the second electronic component are exposed at an access opening to the accommodation volume at the bottom of the clip. This may provide a convenient electrical access to the terminals at a bottom side of the electronic components.

In an embodiment, the bottom of the clip, a bottom of the first electronic component, and a bottom of the second electronic component are at the same vertical level. Thus, the bottoms of clip and electronic components may be in flush with each other. This may simplify an electric and mechanical connection with a mounting base, for instance by providing a common soldering or sintering plane.

In an embodiment, the at least one exposed electrically conductive first terminal comprises at least two (for example three) first terminals and/or the at least one exposed electrically conductive second terminal comprises at least two (for example three) second terminals. Two-terminal electronic components may be diode chips. Three-terminal electronic components may be transistor chips. However, any other number of terminals of the electronic components is possible as well.

In an embodiment, the method comprises manufacturing the first electronic component and the second electronic component as parts of a common encapsulated multi-component body, separating the first electronic component and the second electronic component from the multi-component body, inserting the separated first electronic component and second electronic component into a clip of a common multi-clip body, and subsequently separating the common multi-clip body into individual clips, thereby obtaining a plurality of separate packages. It is also possible to provide separate multi-component bodies for forming first electronic components and for forming second electronic components. In particular referring to FIG. 9, batch manufacture of packages may allow to obtain a high throughput on an industrial scale. Electronic components for packages may be manufactured on the basis of a common encapsulated multi-component body, which can be provided with low cost and which can then be separated for instance by mechanical dicing or laser dicing. Also the clips of different packages may form initially part of a common multi-clip body, which can be manufactured with low effort. By inserting the separated electronic components into individual clip sections of the common multi-clip body and by subsequently separating the common multi-clip body into individual clips, a plurality of packages may be manufactured in a fast and efficient way.

In an embodiment, the package is configured as power package. A power package may be a package comprising at least one power chip as electronic component(s). Thus, the package may be configured as power module, for instance molded power module such as a semiconductor power package. For instance, an exemplary embodiment of the package may be an intelligent power module (IPM). Another exemplary embodiment of the package is a dual inline package (DIP).

Correspondingly, the electronic components may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning isolation are particularly pronounced for power dies.

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment.

FIG. 2 illustrates a side view of the package according to FIG. 1.

FIG. 3 illustrates a bottom view of the package according to FIG. 1.

FIG. 4 illustrates a side view of a package according to an exemplary embodiment.

FIG. 5 illustrates a three-dimensional view of the package according to FIG. 4.

FIG. 6 illustrates cross-sectional views of structures obtained during manufacturing a package according to an exemplary embodiment.

FIG. 7 illustrates a cross-sectional view of a package according to an exemplary embodiment.

FIG. 8 illustrates a cross-sectional view of a package according to another exemplary embodiment.

FIG. 9 illustrates different views of structures obtained during manufacturing packages according to an exemplary embodiment.

FIG. 10 illustrates a cross-sectional view of a package according to another exemplary embodiment.

FIG. 11 illustrates a cross-sectional view of a package according to still another exemplary embodiment.

FIG. 12 illustrates a cross-sectional view of a package according to another exemplary embodiment.

FIG. 13 illustrates a side view of the package according to FIG. 12.

FIG. 14 illustrates a bottom view of the package according to FIG. 12.

FIG. 15 illustrates a flowchart of a method of manufacturing a package according to an exemplary embodiment.

### DETAILED DESCRIPTION

The illustrations in the drawings are schematic and not to scale.

Before exemplary embodiments will be described in more detail referring to the figures, some general considerations will be summarized based on which exemplary embodiments have been developed.

There is a continued trend of miniaturization in packaging of semiconductor dies. However, conventional packaging designs arrive more and more at technological limits.

According to an exemplary embodiment, a vertical package is provided with two or more vertically extending electronic components. The vertical components may have exposed terminals. A clip accommodates the electronic components in its interior and holds (for instance clamps, and/or connects integrally by a connection medium such as solder) the electronic components together for connecting them mechanically, and preferably for simultaneously establishing an electric coupling in between. Advantageously, the terminals of the at least two held electronic components are accessible electrically at the bottom of the clip, for instance indirectly by the clip and/or directly by an accessible end of the electronic components at the bottom of the accommodation volume, or indirectly by one or more other conductive elements. Advantageously, the vertical orientation of the electronic components in their assembled state in the clip may lead to a compact package with high electric and mechanical reliability. A corresponding manufacturing process is very simple, and only requires insertion of the vertical electronic components in the accommodation volume where they may be automatically clamp connected and/or integrally connected by a connection material or medium. As a result, a package may be obtained which is compact in size, may show excellent reliability and may be manufactured in a simple fashion.

What concerns dimensioning of SMD (surface mounted device) packages, a vertical package can offer a compact footprint design, with double sided cooling option. Also large chip-package contact areas may be achieved with vertical packages. This may lead to a low package resistance (for example a reduction of the Rdson value by approximately 60% for a dual chip configuration). Moreover, a vertical package offers the possibility of an oppositely directed current flow in the package which may result in low radiated emissions. Furthermore, an improved temperature cycling on board (TCoB) characteristics may be achieved by packages according to exemplary embodiments. Furthermore, the package design according to exemplary embodiments may offer a high creepage distance. Beyond this, a potential separation of the two (or more) electronic components during processes such as reflow may be reliably prevented according to exemplary embodiments.

Advantageously, an exemplary embodiment may create a flat package to package stack. A clip, for instance embodied as U-shaped clip (for instance in frame form) may be provided to clamp from a top and/or central side to stabilize the structure and make electric contacts accessible at a bottom side. Additionally or alternatively to clamping, a clip may also form an integral connection structure with the electronic components. Advantageously, such a manufacturing concept may be generally applicable to very different package types, in particular to all double-sided cooling packages. A package according to an exemplary embodiment may be configured as vertical package with low Rdson packaging DC-DC characteristics, excellent power regulation, and high-power efficiency.

In different embodiments, a vertical package may be provided which is configured with single or dual chip design.

Thus, exemplary embodiments provide a way to enable a compact package design in vertical package configuration. At the same time, exemplary embodiments may solve challenges of vertical packages having concerns such as TCoB, creepage distance, the risk of package separation during processes such as reflow, thermal dissipation.

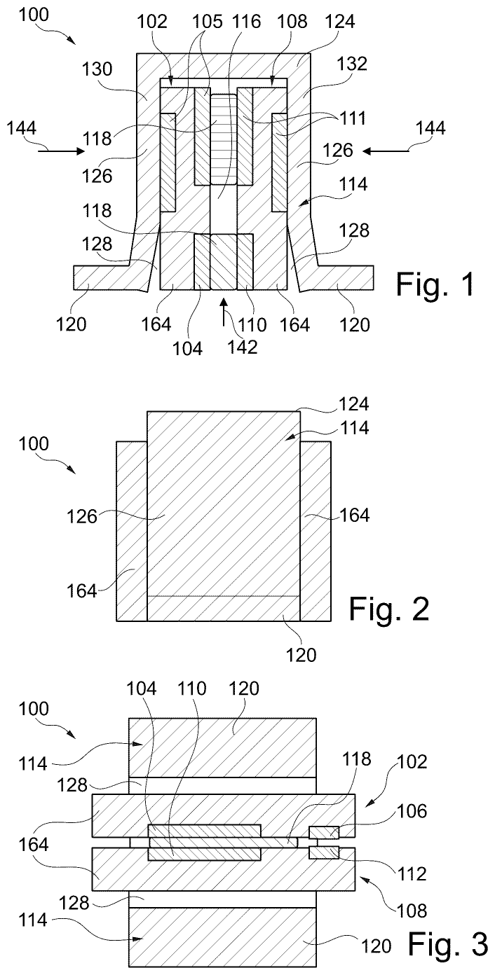

FIG. 1 illustrates a cross-sectional view of a package 100 according to an exemplary embodiment. FIG. 2 illustrates a side view of the package 100 according to FIG. 1. FIG. 3 illustrates a bottom view of the package 100 according to FIG. 1 and FIG. 2. The illustrated package 100 is a vertical power semiconductor package.

A vertically extending first electronic component 102 comprises a semiconductor chip (for example a bare die, not shown) encapsulated by an encapsulant 164, such as a mold compound. Although not shown, a chip carrier (such as a leadframe structure carrying the semiconductor chip) may be arranged inside the encapsulant 164 of the first electronic component 102. The semiconductor chip provides a transistor function in the shown embodiment, for example a field-effect transistor functionality. The vertically extending first electronic component 102 comprises three exposed electrically conductive first terminals 104-106. A first terminal 104 is a source terminal. A second terminal 105 is a drain terminal. A third terminal 106 is a gate terminal. The first electronic component 102 extends vertically in the illustrated assembled state so that its first terminals 104-106 are exposed at vertical sidewalls of the first electronic component 102.

Furthermore, a vertically extending second electronic component 108 comprises a semiconductor chip (for example a bare die, not shown) encapsulated by an encapsulant 164, such as a mold compound. Although not shown, a chip carrier (such as a leadframe structure carrying the semiconductor chip) may be arranged inside the second electronic component 108. The semiconductor chip provides a transistor function in the shown embodiment, for example a field-effect transistor functionality. The vertically extending second electronic component 108 comprises three exposed electrically conductive second terminals 110-112. A first terminal 110 is a source terminal. A second terminal 111 is a drain terminal. A third terminal 112 is a gate terminal. The second electronic component 108 extends vertically so that its second terminals 110-112 are exposed at vertical sidewalls of the second electronic component 108.

In the shown embodiment, the two transistor chips of electronic components 102, 108 form two switches for enhancing switching current. However, other embodiments may involve another electronic functionality, such as a diode functionality, a half bridge functionality, etc. The electronic components 102, 108 may be of the same chip type or may be different types of chips. Moreover, the terminal arrangement according to FIG. 1 may be changed, for instance source, drain and gate terminals may be arranged in another configuration than as shown in FIG. 1 to FIG. 3. Also a larger or smaller number of terminals is possible.

A clip 114 (which can be for example substantially U-shaped) defines an accommodation volume 116 in its interior. In the shown embodiment, clip 114 is made of an electrically conductive material such as a metal so that the clip 114 may also contribute to the electric functionality of the package 100, as will be described below. As shown, the first electronic component 102 and the second electronic component 108 are both accommodated in a horizontally stacked vertical configuration in the accommodation volume 116 and are held by being clamped together by a clamping force exerted by the clip 114 to the stacked electronic components 102, 108. More specifically, clip 114 generates a substantially horizontal clamping force which clamps together the electronic components 102, 108 with each other as well as the clip 114 with the electronic components 102, 108. As a result of the clamping force, the clip 114 and the electronic components 102, 108 form a firmly connected body which can be handled as a whole. When being inserted in their vertical orientation into accommodation volume 116 of clip 114, the electronic components 102, 108 are clamp-connected with the clip 114 and with each other, both by a clamping force generated by the clip 114.

Still referring to FIG. 1, a vertically central portion of the clip 114 directly contacts the first electronic component 102 and the second electronic component 108 including their terminals 105, 111. In contrast to this, the bottom of the clip 114 is laterally spaced with respect to the first electronic component 102 and the second electronic component 108 by a gap at an access opening 128. A bottom of the first electronic component 102 and a bottom of the second electronic component 108 are exposed at the access opening 128 to the accommodation volume 116 at the bottom of the clip 114.

In view of the vertical arrangement or orientation of the electronic components 102, 108, a vertical extension of the first electronic component 102 and of the second electronic component 108 along an insertion direction 142 into the accommodation volume 116 is larger than a horizontal extension of the first electronic component 102 and of the second electronic component 108 along a clamping force direction 144 along which clip 114 exerts a clamping force. Correspondingly, each of the first terminals 104-106 and second terminals 110-112 has an exterior planar surface arranged perpendicular to the clamping force direction 144, i.e. vertically.

The electronic components 102, 108 are inserted from a bottom side of the clip 114 into the accommodation volume 116 of the clip 114 so that the first terminals 104-106 and the second terminals 110-112 are electrically accessible at a bottom of the clip 114 from an exterior side of the package 100. As best seen in FIG. 1 and FIG. 3, terminals 104, 106, 110 and 112 are directly electrically accessible at an exposed portion of the electronic components 102, 108 at the bottom side of the clip 114. Furthermore, terminals 105, 111 being in direct physical contact with wall portions of the clip 114 are electrically accessible at the bottom side of the clip 114 via a lateral extension section 120 of the clip 114. The lateral extension sections 120 may lead to a large solder area. The gull wing design of clip 114 ensures advantageous TCoB properties and allows for properly managing the creepage distance. Advantageously, the electric accessibility of all terminals 104-106, 110-112 at the bottom of the clip 114 allows to simply assemble package 100 on a mounting base 122 (such as a printed circuit board), see FIG. 6, by merely soldering the package 100 onto the mounting base 122. This may be sufficient for establishing an electric connection of all terminals 104-106, 110-112 of package 100 with mounting base 122. Since the bottom of the clip 114, a bottom of the first electronic component 102, and a bottom of the second electronic component 108 are at the same vertical level (see FIG. 1), assembly of package 100 on mounting base 122 may be further promoted. As the clip 114 is electrically conductive, an electrically conductive connection can be established between the clip 114 and terminals 105, 111 by the clamping. Moreover, the clamping force holds together the electronic components 102, 108 for promoting an electric connection between terminals 105, 111, between terminals 104 and 110, and optionally between terminals 112 and 106. Terminals 105, 111 are electrically accessible at the bottom of the clip 114 indirectly by being electrically coupled with the clip 114 which is made of an electrically conductive material. Furthermore, terminals 104, 106, 110, 112 are electrically accessible directly at an exposed bottom of the first electronic component 102 and of the second electronic component 108, respectively. To put it shortly, the clamping functionality of clip 114 may promote a mechanical connection between electronic components 102, 108 and clip 114 and may also establish an electric connection between electronic components 102, 108 and clip 114.

As best seen in FIG. 1 and FIG. 3, package 100 further comprises an optional component connection medium 118, such as solder, connecting the first electronic component 102 with the second electronic component 108 in the accommodation volume 116. More specifically, connection medium 118 may connect terminals 104, 110, and may connect terminals 105, 111 by a solder connection. As an alternative to a solder, connection medium 118 may also be an electrically conductive glue or a sinter material.

In the illustrated embodiment, the clip 114 has a horizontally extending closed head 124 connecting to a vertically extending lateral clamping section 126 delimiting said accommodation volume 116 and leading up to an end-sided exterior access opening 128. More specifically, the clip 114 of FIG. 1 to FIG. 3 is a clip with two legs 130, 132 connected by the closed head 124. This configuration protects the electronic components 102, 108 accommodated by clip 114, provides the clamping functionality and contributes to the electric functionality as well. Furthermore, the clip 114 has a lateral extension section 120 at its bottom extending horizontally from the lateral clamping section 126. This may increase the connection area usable for assembling package 100 on a mounting base 122 (see FIG. 6).

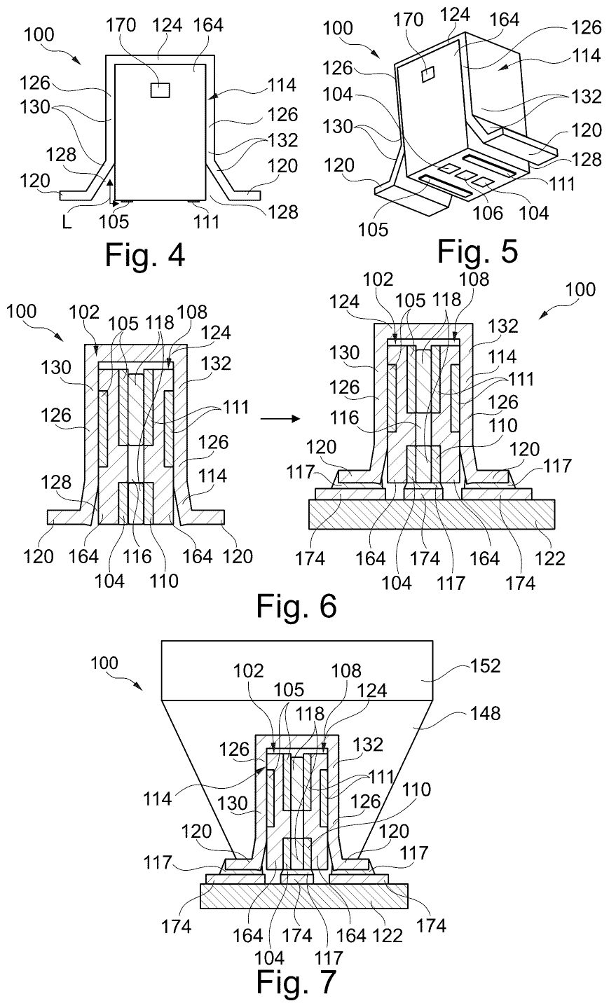

FIG. 4 illustrates a side view of a package 100 according to an exemplary embodiment. FIG. 5 illustrates a three-dimensional view of the package 100 according to FIG. 4.

In the embodiment according to FIG. 4 and FIG. 5, vertical sidewall portions of the package 100 are formed by the lateral clamping sections 126 of clip 114, by exposed main surfaces of encapsulant 164 of the electronic components 102, 108, and by tie bars 170 through which individual packages 100 are separated by dicing. As best seen in FIG. 5, terminals 104-106, 111 are directly exposed at a bottom of the connected electronic components 102, 108 (not indicated individually in FIG. 4 and FIG. 5).

With the clip-type clamping arrangement of FIG. 4 and FIG. 5, the top surface of the package 100 becomes flat at head 124. This is highly advantageous in terms of an easy component pick up, in particular when assembling larger electronic devices.

Also concerning creepage distance, package 100 of FIG. 4 and FIG. 5 offers the advantage of enhancing the creepage characteristics from ‘limit by package thickness’ to ‘limit by package surface’. Due to a gap at access opening 128, the creepage distance, L, can be increased compared with conventional approaches. Due to the design of FIG. 4 and FIG. 5, a positive impact on board level assembly may be achieved, for instance when assembling the illustrated package 100 on a mounting base 122.

FIG. 6 illustrates cross-sectional views of structures obtained during manufacturing a package according to an exemplary embodiment.

On the left-hand side of FIG. 6, a package according to FIG. 1 is shown. This package 100 is mounted on a mounting base 122 on the right-hand side of FIG. 6. The mounting base 122 may for instance be a leadframe or a printed circuit board. For this assembly, electrically conductive structures 174 (such as pads) on the surface of the mounting base 122 may be connected with the lateral extension section 120 and with the exposed terminals 104, 106, 110, 112 (only partially visible in FIG. 6) with mounting base connection medium 117 in between. This can be accomplished by mounting base connection medium 117 embodied as solder, sinter or conductive glue. By the electric accessibility of all terminals 104-106, 110-112 of the clamp-connected electronic components 102, 108 at the bottom of the clip 114, a simple and planar assembly of package 100 on mounting base 122 may be enabled. Thus, the mounting base 122 can be electrically and mechanically connected with the first electronic component 102, the second electronic component 108, and the clip 114 at its bottom during an assembly process.

Further advantageously, a bottom portion of legs 130, 132 tapers towards head 124 so that access opening 128 forms a gap between the electronic components 102, 108 on the one hand and the lateral extension section 120 on the other hand. This creates a large creepage distance.

Optionally, a source/gate pad may be closed with glue at the illustrated sandwich structure. The connection structure (such as solder) can close gaps, and may also increase the soldering area for achieving a better TCoB or a low ohmic contact.

FIG. 7 illustrates a cross-sectional view of a package 100 according to an exemplary embodiment.

As shown in FIG. 7, package 100 may comprise a thermal interface (TIM) body 148 having a recess receiving the upper portion of the clip 114. Furthermore, a heat sink 152 (which is illustrated schematically in FIG. 7) may be attached to an exterior of the thermal interface body 148. Advantageously, the thermal interface body 148 may taper from said heat sink 152 towards said clip 114. The thermal interface body 148 may be made of a material having a proper thermal conductivity, for instance may comprise thermal paste or grease or the like. Thus, the thermal interface body 148 may reduce the thermal barrier between the clip 114 and the heat sink 152, which may be made of a highly thermally conductive material such as aluminum or copper. The illustrated arrangement provides a very high contact area and consequently a very low thermal contact resistance between clip 114 and heat sink 152. Thus, heat generated by the electronic components 102, 108 during operation of package 100 may be removed highly efficiently via thermal interface body 148 to heat sink 152, and may be dissipated from here towards an environment. The tapering configuration of the thermal interface body 148 may spread heat towards a bigger area of heat sink 152, which may render heat removal highly efficient.

Thus, the package 100 may have thermal contact with TIM and the heat sink 152. In this context, the U-shaped clip structure of clip 114 may provide a large contact area. This may lead to a package 100 with excellent thermal performance.

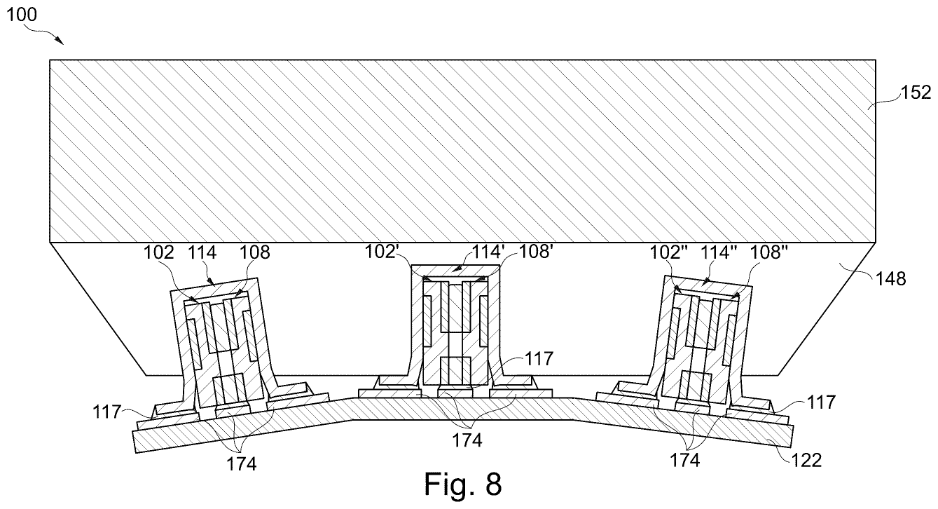

FIG. 8 illustrates a cross-sectional view of a package 100 according to still another exemplary embodiment. The embodiment of FIG. 8 differs from the embodiment of FIG. 7 in particular in that, according to FIG. 8, a plurality of clips 114 with electronic components 102, 108 clamped therein are connected with one in the same thermal interface body 148 and one of the same heat sink 152. This may render thermal dissipation of heat even more efficient.

More specifically, package 100 according to FIG. 8 additionally comprises two further first electronic components 102′, 102″, two further second electronic components 108′, 108″ and two further clips 114′, 114″ with the features as described referring to FIG. 1 to FIG. 3 for first electronic component 102, second electronic component 108 and clip 114. A common mounting base 122, such as a PCB, is connected with the clip 114, the first electronic component 102, the second electronic component 108, the two further clips 114′, 114″, the two further first electronic components 102′, 102″ and the two further second electronic components 108′, 108″. Moreover, a common thermal interface body 148 has three recesses receiving top parts of the clip 114 and the two further clips 114′, 114″. This configuration simplifies assembly of members providing even sophisticated electric functionality with efficient heat removal and heat spreading at low space consumption. Furthermore, the illustrated arrangement of FIG. 8 provides an improved warpage management.

Hence, with small footprint of the package 100 (where electronic components can be placed close on a PCB) and large area of contact to a TIM, the impact of thermal resistance variation or bottlenecks concerning an application can be reduced or even minimized.

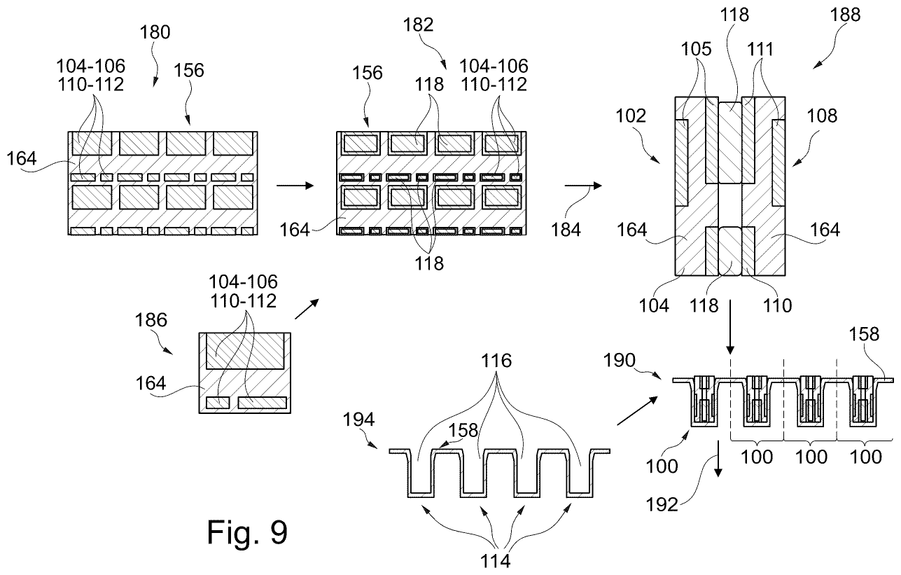

FIG. 9 illustrates different views of structures obtained during manufacturing packages 100 according to an exemplary embodiment. The shown batch manufacturing process is highly efficient and allows the manufacture of packages 100 with high throughput on an industrial scale.

Referring to reference sign 180, the first electronic components 102 and the second electronic components 108 are manufactured as parts of a common encapsulated multi-component body 156. Alternatively, the first electronic components 102 are manufactured as parts of a common encapsulated multi-component body 156, and the second electronic components 108 are manufactured as parts of another common encapsulated multi-component body 156. Terminals 104-106, 110-112 of the electronic components 102, 108 may be exposed beyond encapsulant 164, which may be a mold compound. According to reference sign 180, the terminals 104-106, 110-112 or pads may be tin plated.

Referring to reference sign 182, the multi-component body 156 is shown after forming connection medium 118 on the exposed terminals 104-106, 110-112. For instance, the connection medium 118 may be formed by conductive paste printing. This process may be optional, for example when the respective pad or terminal can form an interconnection which is non-remelting sensitive.

Referring to reference sign 184, the obtained structure may be subjected to a singulation process (and optionally a glue cure process). By taking this measure, the first electronic components 102 and the second electronic components 108 are separated from one or different multi-component bodies 156.

Reference sign 186 shows a mirror singulated package structure which may be subjected to a pick and place process.

Optionally, a respective first electronic component 102 and a respective second electronic component 108 may be stacked, optionally with connection medium 118 in between (see reference sign 188).

Stacked pairs of a separated first electronic component 102 and a separated second electronic component 108 are inserted in a vertical orientation into a clip 114 of a common multi-clip body 158, see reference sign 190. Thus, a sandwich of electronic components 102, 108 may be inserted into a U-clip frame. The common multi-clip body 158 comprises a plurality of integrally formed clips 114 (see reference sign 194; an incoming U-clip frame can be for example plated, for instance tin plated or pre-processed in another way). More specifically, a vertically extending first electronic component 102 with at least one exposed electrically conductive first terminal 104-106 is inserted in an accommodation volume 116 of a clip 114 together with a vertically extending second electronic component 108 with at least one exposed electrically conductive second terminal 110-112. The first electronic component 102 and the second electronic component 108 are clamped together in the accommodation volume 116 by a clamping force generated by the clip 114. Advantageously, the first electronic component 102, the second electronic component 108 and the clip 114 are configured so that the at least one first terminal 104-106 and the at least one second terminal 110-112 are electrically accessible at a bottom of the clip 114.

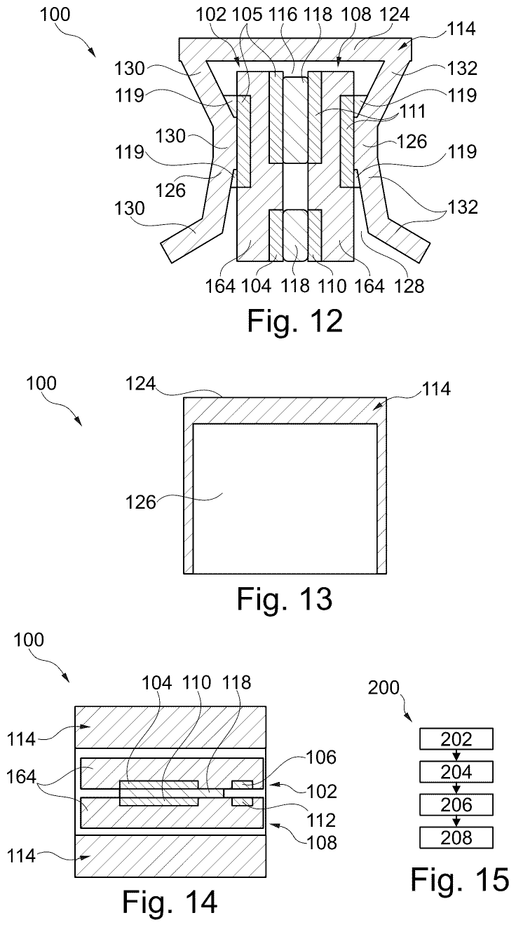

Additionally or alternatively to clamping the electronic components 102, 108 together by a clamp-type clip 114, it is also possible to hold the electronic components 102, 108 together by a clip 114 which is connected to the electronic components 102, 108 by a connection medium (see for instance reference signs 118, 119 in FIG. 12).

Now referring to reference sign 192, the common multi-clip body 156 with the inserted electronic components 102, 108 is separated (for instance by stamp singulation) into individual clips 114 each having a pair of inserted clamp-connected electronic components 102, 108, thereby obtaining a plurality of separate packages 100.

One or more further processes may be carried out at the end of the manufacture, such as plating, laser marking, clip to TSC fusion annealing, stamp singulation.

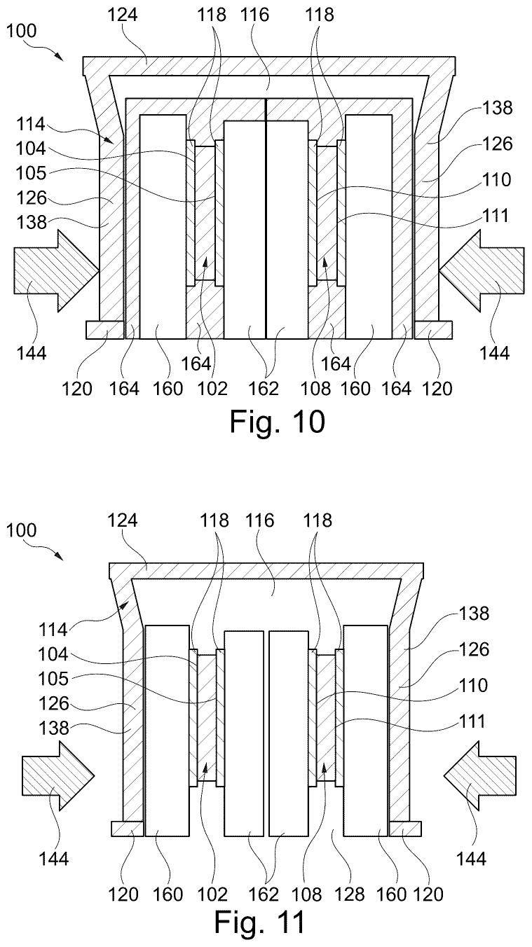

FIG. 10 illustrates a cross-sectional view of a package 100 according to another exemplary embodiment.

In FIG. 10, the electronic components 102, 108 each comprise a bare die connected via connection medium 118 with a pair of parallel conductive elements 160, 162. For instance, such conductive elements 160, 162 may comprise a chip carrier (such as a leadframe structure or a metal plate, or any other connector), a metallic clip, etc. It is also possible to provide only one conductive element 160, 162 per electronic component 102, 108. In the shown embodiment, the conductive elements 160, 162 are exposed beyond the respective encapsulant 164 and are accessible at a bottom side of clip 114 for providing electric access to the assigned terminals 104, 105, 110, 111. Thus, the conductive elements 160, 162 interconnect the respective semiconductor chips of the electronic components 102, 108 to the bottom side of the package 100. Hence, terminals 104, 105, 110, 111 are electrically accessible at the bottom of the clip 114 by being electrically coupled with the electrically conductive elements 160, 162 extending vertically in the accommodation volume 116 up to the bottom of the clip 114.

In the embodiment of FIG. 10, it may be for instance possible that said clip 114 is a cap with closed head 124 connected with a circumferentially closed clamping sleeve 138. To put it shortly, the embodiment of FIG. 10 may rely on a four-sided or circumferentially closed lid or cap rather than on a two-sided or two-leg clip (as for instance in FIG. 1). FIG. 10 thus shows that, instead of using a U-clip, a lid can be used as clip 114. According to FIG. 10, sleeve 138 is embodied as a centrally confined sleeve which may further enhance the clamping performance of clip 114.

According to FIG. 10, clip 114 provides only a mechanical clamping force (exerted in clamping force direction 144) and does not conduct electricity. Thus, clip 114 of FIG. 10 may be also made of an electrically insulating material, such as a plastic. However, clip 114 has an electronic functionality in FIG. 10 as well, since it presses the metallic conductive elements 162, 162 of electronic components 102, 108 together, thereby creating an electrically conductive coupling in between.

FIG. 11 illustrates a cross-sectional view of a package 100 according to yet another exemplary embodiment.

The embodiment of FIG. 11 differs from the embodiment of FIG. 10 in particular in that, according to FIG. 11, encapsulant 164 is omitted in both electronic components 102, 108, so that clip 114 directly acts, when exerting a clamping force, on conductive elements 160 of electronic components 102, 108. When clip 114 is made of a metallic material, it may also electrically couple terminals 104 and 111 with each other via conductive elements 160 and the clip 114 itself. Alternatively, clip 114 may be made of an electrically insulating material in FIG. 11 as well. Package 100 according to FIG. 11 is a non-molded package.

FIG. 12 illustrates a cross-sectional view of a package 100 according to another exemplary embodiment. FIG. 13 illustrates a side view of the package 100 according to FIG. 12. FIG. 14 illustrates a bottom view of the package 100 according to FIG. 12.

Contrary to the embodiment of FIG. 1 to FIG. 3, the embodiment of FIG. 12 to FIG. 14 comprises a clip connection medium 119 (for example glue or solder) which integrally connects the clip 114 with the first electronic component 102 and with the second electronic component 108 in the accommodation volume 116. Hence, the connection strength and consequently the reliability of the package 100 according to FIG. 12 to FIG. 14 may be further improved by combining a clamping connection formed by clip 114 with a permanent material connection formed by clip connection medium 119. As shown, a spatially confined central portion of the clip 114 may contact the first electronic component 102 and the second electronic component 108 via the clip connection medium 119 (and/or with direct physical contact).

Referring to FIG. 12, each of legs 130, 132 is confined in a central section where clip 114 clamps onto electronic components 102, 108. Furthermore, each of legs 130, 132 tapers from the bottom of the clip 114 and from the head 124 of the clip 114 towards the central section. On the top side, this leads to an enlarged top surface area enabling improved heat removal. On the bottom side, this results in a higher creepage distance.

Hence, the embodiment of FIG. 12 to FIG. 14 has a different U-clip contact profile than the embodiment of FIG. 1 to FIG. 3. A spot contact clamping profile is provided for enabling an extra soldering point of the package top pad to the clip. Also an increase top cooling area may be achieved with this embodiment. In particular, a primary cooling surface there may lead to a smaller TIM thickness to a heat sink.

It will be understood that a U-clip lead foot shape is also not limited to a gullwing characteristics, but may be embodied also in another way. Also the size of the U-clip is not limited and can be for example bigger or smaller than the plastic package, or may have the same dimensions.

Furthermore, the embodiment of FIG. 12 to FIG. 14 may also be adapted with a clip 114 which does not exert a clamping force to the vertical electronic components 102, 108 for holding them together. In such an embodiment, it may be possible that the clip connection medium 119 alone provides a holding or connection force holding the clip 114, on the one hand, and the electronic components 102, 108, on the other hand, together (i.e. without clamping). A corresponding integral connection which holds the constituents of package 100 according to such an embodiment together may be further enhanced by component connection medium 118 holding together the electronic components 102, 108. In such an embodiment, clip 114 functions as a protection structure defining and providing an accommodation volume 116 in which the electronic components 102, 108 can be accommodated and connected with each other and with the clip 114 by connection medium 118, 119 (such as a solder, a sinter paste, a glue, etc.).

FIG. 15 illustrates a flowchart 200 of a method of manufacturing a package 100 according to an exemplary embodiment. The reference signs used for the following description of said manufacturing method relate to the embodiment of FIG. 1.

Referring to a block 202, the method comprises inserting a vertically extending first electronic component 102 with at least one exposed electrically conductive first terminal 104-106 in an accommodation volume 116 of a clip 114.

Referring to a block 204, the method comprises inserting a vertically extending second electronic component 108 with at least one exposed electrically conductive second terminal 110-112 in the accommodation volume 116 of the clip 114.

Referring to a block 206, the method comprises holding (for instance clamping) together the first electronic component 102 and the second electronic component 108 in the accommodation volume 116 by the clip 114 (and optionally in addition by a connection medium 118 and/or 119).

Referring to a block 208, the method comprises configuring the first electronic component 102, the second electronic component 108 and the clip 114 so that the at least one first terminal 104-106 and the at least one second terminal 110-112 are electrically accessible at a bottom of the clip 114.

As a result, a package 100 may be obtained which comprises a vertically extending first electronic component 102 with at least one exposed electrically conductive first terminal 104-106, a vertically extending second electronic component 108 with at least one exposed electrically conductive second terminal 110-112, and a clip 114 with an accommodation volume 116 in which the first electronic component 102 and the second electronic component 108 are accommodated and are held (for instance clamped) together, wherein the at least one first terminal 104-106 and the at least one second terminal 110-112 are electrically accessible at a bottom of the clip 114.

It should be understood that each and every of the above mentioned embodiments holding electronic components 102, 108 together by a clamping clip 114 only may also be modified with a non-clamping clip 114 in combination with a clip connection medium 119 and/or a component connection medium 118, or with a clamping clip 114 in combination with a clip connection medium 119 and/or a component connection medium 118. Correspondingly, each and every of the above mentioned embodiments holding electronic components 102, 108 together by a non-clamping clip 114 in combination with a clip connection medium 119 and/or a component connection medium 118 may also be modified with a clamping clip 114 with or without a clip connection medium 119 and/or a component connection medium 118.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, described in the specification. Accordingly, the appended claims are intended to include within their scope such processes, machines, manufacture, compositions of matter, means, methods, or steps.

What is claimed is:

1. A package, comprising:
a vertically extending first electronic component with at least one exposed electrically conductive first terminal;
a vertically extending second electronic component with at least one exposed electrically conductive second terminal; and
a clip with an accommodation volume in which the first electronic component and the second electronic component are accommodated and are held together,
wherein the at least one first terminal and the at least one second terminal are electrically accessible at a bottom of the clip.

2. The package of claim 1, further comprising a component connection medium connecting the first electronic component with the second electronic component in the accommodation volume.

3. The package of claim 2, wherein the component connection medium connects at least one of the at least one first terminal and at least one of the at least one second terminal with each other.

4. The package of claim 1, further comprising a clip connection medium connecting the clip with at least one of the first electronic component and the second electronic component in the accommodation volume.

5. The package of claim 1, wherein the clip is configured to clamp together the first electronic component and the second electronic component in the accommodation volume by a clamping force.

6. The package of claim 1, wherein at least one of the first electronic component and the second electronic component is a bare die, a die encapsulated by an encapsulant, a plurality of dies encapsulated by an encapsulant, a bare die mounted on a conductive element, or a bare die connected between two conductive elements.

7. The package of claim 1, wherein the clip is electrically conductive.

8. The package of claim 7, wherein an electrically conductive connection is established between the clip and at least one of the at least one first terminal and the at least one second terminal by a holding force.

9. The package of claim 1, wherein an electrically conductive connection is established between at least one of the at least one first terminal and at least one of the at least one second terminal by a holding force.

10. The package of claim 1, wherein the clip has a lateral extension section at the bottom of the clip.

11. The package of claim 1, further comprising a mounting base electrically and mechanically connected with the first electronic component, the second electronic component, and the clip at the bottom of the clip.

12. The package of claim 1, wherein the clip has a head connected to a lateral holding section delimiting the accommodation volume and leading up to an end-sided exterior access opening.

13. The package of claim 1, wherein the clip has two spaced legs connected by a head, or is a cap with a head connected with a circumferentially closed holding sleeve.

14. The package of claim 1, wherein a vertical extension of the first electronic component and/or of the second electronic component along an insertion direction into the accommodation volume is larger than another extension of the first electronic component and/or of the second electronic component perpendicular to the insertion direction.

15. The package of claim 1, further comprising a thermal interface body having a recess receiving at least part of the clip.

16. The package of claim 15, further comprising a heat sink attached to an exterior of the thermal interface body.

17. The package of claim 16, wherein the thermal interface body tapers from the heat sink towards said clip.

18. The package of claim 1, wherein at least one of:
each of the at least one first terminal and the at least one second terminal has an exterior planar surface arranged vertically;
at least one of the at least one first terminal and the at least one second terminal is electrically accessible at the bottom of the clip by being electrically coupled with the clip which comprises an electrically conductive material;
at least one of the at least one first terminal and the at least one second terminal is electrically accessible directly at an exposed bottom of the first electronic component and/or at an exposed bottom of the second electronic component;
at least one of the at least one first terminal and the at least one second terminal is electrically accessible at the bottom of the clip by being electrically coupled with an electrically conductive element extending vertically in the accommodation volume up to the bottom of the clip;
a spatially confined central portion of the clip contacts the first electronic component and the second electronic component directly or via a clip connection medium;
a central portion of the clip is connected with the first electronic component and the second electronic component, with the bottom of the clip being laterally spaced by a gap with respect to the first electronic component and the second electronic component;
at least one of the first electronic component and the second electronic component comprises a transistor chip;
at least one of the first electronic component and the second electronic component comprises a semiconductor power chip;
the package further comprises at least one further first electronic component, at least one further second electronic component, at least one further clip, and a common mounting base connected with the clip, the first electronic component, the second electronic component, the at least one further clip, the at least one further first electronic component and the at least one further second electronic component;
the package further comprises at least one further first electronic component, at least one further second electronic component, at least one further clip, and a common thermal interface body with recesses receiving at least part of the clip and at least part of the at least one further clip;
a bottom of the first electronic component and a bottom of the second electronic component are exposed at an access opening to the accommodation volume at the bottom of the clip;
the bottom of the clip, a bottom of the first electronic component, and a bottom of the second electronic component are at a same vertical level; and
the at least one exposed electrically conductive first terminal comprises at least two first terminals and/or the at least one exposed electrically conductive second terminal comprises at least two second terminals.

19. A method of manufacturing a package, the method comprising:
inserting a vertically extending first electronic component with at least one exposed electrically conductive first terminal in an accommodation volume of a clip;
inserting a vertically extending second electronic component with at least one exposed electrically conductive second terminal in the accommodation volume of the clip;
holding together the first electronic component and the second electronic component in the accommodation volume by the clip; and
configuring the first electronic component, the second electronic component, and the clip so that the at least one first terminal and the at least one second terminal are electrically accessible at a bottom of the clip.

20. The method of claim 19, further comprising:
manufacturing the first electronic component and the second electronic component as parts of a common encapsulated multi-component body;
separating the first electronic component and the second electronic component from the multi-component body;
inserting the separated first electronic component and second electronic component into a clip of a common multi-clip body; and
subsequently separating the common multi-clip body into individual clips to obtain a plurality of separate packages.
